(19) United States
(12) Patent Application Publication
(10) Pub. No.: US 2026/0331952 A1
(43) Pub. Date: Oct. 22, 2026

(54) Wireless Charging Stand

(71) Applicant: Anker Innovations Technology Co., Ltd., Changsha (CN)

(72) Inventors: Wei Chen, Shenzhen (CN); Hongfu Mo, Shenzhen (CN); Zhang Gao, Shenzhen (CN); Songya Chen, Shenzhen (CN)

(21) Appl. No.: 19/653,237

(22) Filed: Apr. 21, 2026

(30) Foreign Application Priority Data
Apr. 21, 2025 (CN) 202520767651.7

(51) Int. Cl. H02J 50/00; H02J 50/10; H02J 50/90; H05K 5/02; H05K 7/20

(52) U.S. Cl. CPC H02J 50/005; H02J 50/10; H02J 50/90; H05K 5/0204; H05K 5/0209; H05K 5/0214; H05K 7/20918

(57) ABSTRACT

Disclosed is a wireless charging stand comprising: a charging coil; a cooler having a cold end and a hot end disposed opposite each other, the cold end being connected to the charging coil; and a heat sink including a heat dissipation body that is connected to the hot end and provided with an inclined surface. The inclined surface and the cooler may define a heat dissipation space.

### CROSS-REFERENCE TO RELATED APPLICATION

This application claims priority to CN Application No. 202520767651.7, filed April 21, 2025, which is hereby incorporated by reference in its entirety.

### FIELD

The present disclosure relates to the technical field of charging devices, in particular to a wireless charging stand.

### BACKGROUND

In fast-paced life scenarios, frequency of using electronic devices such as mobile phones is increasing, leading to an increase in power consumption speed of the mobile phones, and insufficient battery life of mobile phones has become a practical problem that needs to be solved. Due to advantages of convenient installation and use, high charging efficiency, and wide application scenarios, wireless charging stands have become preferred products for charging mobile phones. However, during operation of the wireless charging stands, charging coils can generate a large amount of heat, and the heat is conducted to the mobile phones, which affects the charging efficiency.

### SUMMARY

In view of the above problem, it is advantageous to provide a wireless charging stand to solve the problem that charging coils generate heat and reduce the charging efficiency.

The present disclosure provides a wireless charging stand including: a charging coil; a cooler having a cold end and a hot end disposed opposite each other, the cold end being connected to the charging coil; and a heat sink including a heat dissipation body that is connected to the hot end and provided with an inclined surface, the inclined surface and the cooler enclosing a heat dissipation space.

The wireless charging stand of this technical solution is applied to a case of charging power-consuming devices such as mobile phones, and during use, a mobile phone is placed on the wireless charging stand to energize the charging coil, and the charging coil may charge the mobile phone wirelessly.

During this process, the charging coil continuously generates a large amount of heat, the heat is conducted to the hot end of the cooler via the cold end of the cooler, and then conducted into the heat sink via the hot end, a part of the heat entering the heat sink is directly dissipated to an external environment through a heat dissipation path of the heat sink, and another part of the heat reaches the heat dissipation space defined (e.g., enclosed) by the inclined surface, the heat dissipation body, and/or the cooler to exchange heat with air in the heat dissipation space, thus being directly dissipated to the external environment, such that the heat in the heat sink may be more efficiently dissipated via two heat dissipation paths, thereby improving the heat dissipation efficiency of the heat sink, strengthening the cooling effect on the charging coil, and ensuring the charging efficiency of the mobile phone.

In an example, a side surface of the heat dissipation body facing away from the cooler is provided with a bump structure configured to improve heat transfer efficiency between the heat sink and air.

In an example, the wireless charging stand further includes a vapor chamber disposed between the charging coil and the cooler.

In an example, the wireless charging stand further includes a heat insulation layer disposed behind the hot end of the cooler and configured to block heat dissipated from the heat sink from diffusing to the hot end of the cooler.

In an example, the wireless charging stand further includes a base housing, a sidewall of which is provided with a heat dissipation window, wherein the heat sink is disposed inside the base housing, and the heat sink further includes heat dissipation fins mounted on a side surface of the heat dissipation body facing away from the cooler, the heat dissipation fins facing the heat dissipation window or at least part of the heat dissipation fins extend into the heat dissipation window.

In an example, the wireless charging stand further includes a wiring circuit board, wherein the heat sink further includes an extension portion disposed on the side surface of the heat dissipation body facing away from the cooler and enclosing an installation recess, the wiring circuit board is disposed in the installation recess, and at least part of a side surface of the extension portion facing away from the installation recess is provided with the heat dissipation fins.

In an example, the wireless charging stand further includes a heat dissipation fan, a plurality of the heat dissipation fins are circumferentially disposed on the heat dissipation body and are all inclined toward a same circumferential direction, and the plurality of heat dissipation fins, the cooler, and/or the heat dissipation body define (e.g., enclose) an accommodating cavity, adjacent two of the heat dissipation fins are disposed at intervals to form a heat dissipation channel, one end of the heat dissipation channel is in communication with the accommodating cavity, and the other end of the heat dissipation channel is in communication with the heat dissipation window, such that the heat dissipation fan is in communication with the external environment.

In an example, the wireless charging stand further includes: a dust gauze, wherein a bottom wall of the base housing is provided with a vent, the dust gauze is disposed between the bottom wall of the base housing and the heat sink, and the dust gauze covers the vent; a rotary body and a fixed base, wherein a side surface of the fixed base facing the rotary body is recessed to form a rotary recess, the rotary body is disposed on the base housing, and the rotary body is rotatably mounted in the rotary recess; and a fixing clamp disposed on the fixed base.

In an example, the wireless charging stand further includes a surface cover connected and fixed to the base housing, wherein a thermally conductive medium is disposed between the side surface of the surface cover facing the base housing and the charging coil.

In an example, the wireless charging stand further includes a cold conducting plate disposed between the charging coil and the cold end of the cooler.

In an example, the wireless charging stand further includes a carrier plate disposed at the surface cover, wherein the carrier plate is provided with a positioning recess, and both the cold conducting plate and the charging coil are mounted in the positioning recess.

### BRIEF DESCRIPTION OF THE DRAWINGS

The accompanying drawings, which form a part of the present disclosure, are used to provide a further understanding of the present disclosure. The schematic examples of the present disclosure and illustrations thereof are used to explain the present disclosure, but are not intended to limit the present disclosure.

In order to more clearly illustrate technical solutions in the present disclosure, drawings that need to be used in description of the examples are briefly introduced below, and it will be apparent to those of ordinary skill in the art that the drawings in the following description are only some examples of the disclosure, and other drawings can be obtained in accordance with these drawings without inventive work.

FIG. 1 is a structure diagram of a wireless charging stand according to an example of the present disclosure.

FIG. 2 is an exploded structure diagram of the wireless charging stand in FIG. 1.

FIG. 3 is an installation structure diagram of a heat sink and a cooler.

FIG. 4 is an installation structure diagram of a heat sink, a cooler, and a charging coil.

FIG. 5 is a structure diagram of a heat sink according to an example.

FIG. 6 is a structure diagram of FIG. 5 from another viewing angle.

FIG. 7 is an exploded structure diagram of a wireless charging stand from another viewing angle.

FIG. 8 is an assembly structure diagram of a heat dissipation fan, a heat sink, and a wiring circuit board.

### DESCRIPTION OF REFERENCE SIGNS

100, wireless charging stand; 10, charging coil; 20, cooler; 30, heat sink; 31, boss; 311, inclined surface; 32, heat dissipation fin; 33, heat dissipation body; 34, accommodating cavity; 35, heat dissipation channel; 36, bump structure; 37, vapor chamber; 38, heat insulation layer; 39, wiring circuit board; 39a, extension portion; 391a, installation recess; 40, heat dissipation space; 50, base housing; 51, heat dissipation window; 60, heat dissipation fan; 70, dust gauze; 80, annular foam; 90, rotary body; 90a, fixed base; 91a, rotary recess; 90b, fixing clamp; 90c, surface cover; 90d, cold conducting plate; 90e, carrier plate; 91e, positioning recess; 90f, magnet; 90g, main circuit board.

### DETAILED DESCRIPTION

In order to make the above objects, features and advantages of the present disclosure more obvious and easier to understand, specific examples of the present disclosure will be described in detail with reference to the drawings. Numerous specific details are set forth in the following description to thoroughly understand the present disclosure. However, the present disclosure can be implemented in many other ways different from those described herein, similar improvements can be made by those skilled in the art without departing from the spirit of the present disclosure, and thus the present disclosure is not limited by specific examples to be disclosed below.

In description of the disclosure, it should be understood that orientation or position relationships indicated by the terms “center”, “longitudinal”, “transverse”, “length”, “width”, “thickness”, “upper”, “lower”, “front”, “rear”, “left”, “right”, “vertical”, “horizontal”, “top”, “bottom”, “inside”, “outside”, “clockwise”, “counterclockwise”, “axial”, “radial”, “circumferential”, and the like are based on the orientation or position relationships shown in the drawings, which are only for the convenience of describing the disclosure and simplifying the description, and do not indicate or imply that the referred device or element must have a specific orientation and be constructed and operated in a specific orientation, and thus cannot be understood as a limit of the disclosure.

In addition, the terms “first”, “second” and “third” herein are used for a descriptive purpose only and are not to be construed as indicating or implying the relative importance or implicitly indicating the number of indicated technical features. Thus, features defined with “first” and “second” may explicitly or implicitly include at least one of such features. In the description of the present disclosure, “a plurality of” means at least two, for example, two, three, and so on, unless otherwise explicitly and specifically defined herein.

In the present disclosure, terms such as “mount”, “communicate”, “connect”, and “fix” should be understood broadly unless expressly specified or defined. For example, the terms may refer to fixed connection, detachable connection, or integration; may refer to mechanical connection or electrical connection; may refer to direct connection, indirect connection via an intermediary, or internal communication or interaction relationship between two elements, unless expressly defined. Specific meanings of the above terms in the present disclosure may be understood by those of ordinary skill in the art in light of specific circumstances.

In the present disclosure, unless otherwise explicitly specified and defined, if a first feature is described as “above” or “below” a second feature, it may mean that the first and second features are in direct contact or in indirect contact through an intermediary. Furthermore, the first feature being “above”, “upon” and “on” the second feature may be the first feature being directly above or obliquely above the second feature, or simply mean that the first feature is higher than the second feature in the horizontal height. Furthermore, the first feature being “below”, “beneath” and “under” the second feature may be the first feature being directly below or obliquely below the second feature, or simply mean that the first feature is lower than the second feature in the horizontal height.

It should be noted that if an element is referred to as “fixed to” or “disposed on” another element, it may be directly on the other element or a middle element may be present. If an element is considered to be “connected” to another element, it may be directly connected to the other element or a middle element may be present. If present, the terms “vertical”, “horizontal”, “upper”, “lower”, “left”, “right” and similar expressions used herein are for the purpose of description only and are not intended to be the only examples.

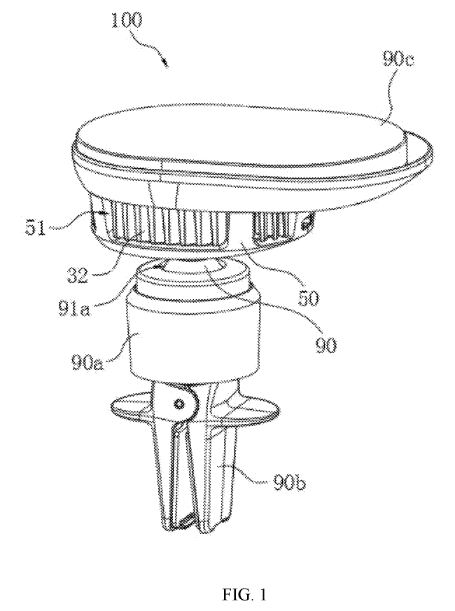

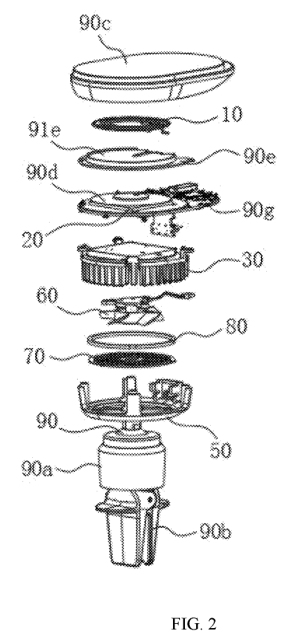

Referring to FIGS. 1 and 2, shown is a wireless charging stand 100 according to an example of the present disclosure, including a charging coil 10, a cooler 20, and a heat sink 30.

The charging coil 10 is a core component of wireless charging technology, which mainly uses the electromagnetic induction principle to achieve wireless transmission of energy. For example, a transmitting end coil is connected to a power supply, generating changing magnetic fields through an alternating current. A receiving end coil induces the magnetic fields and generates an electromotive force, and converts the alternating current into a direct current through a rectification and voltage stabilizing circuit to supply power to a battery or other electronic devices. The charging coil 10 enables a device to be charged without a physical connection such as cable connection, improving convenience and safety of use.

For example, the charging coil 10 in the present disclosure has a spiral structure, and may be one of a single-layer coil, a multi-layer coil, and the like, and a material thereof may be any one of copper, aluminum, and the like, which may be flexibly selected according to actual needs.

The cooler 20 may include a TEC (Thermo Electric Cooler)(e.g., a semiconductor cooler 20), which operates by the Peltier effect. When a current passes through a galvanic couple composed of a p-type semiconductor and an n-type semiconductor, one end thereof absorbs heat to form a cold end, and the other end thereof releases heat to form a hot end. The temperature of the cold end may be controlled by adjusting the magnitude and direction of the current, and typically may reach -20 to -10 degrees Celsius.

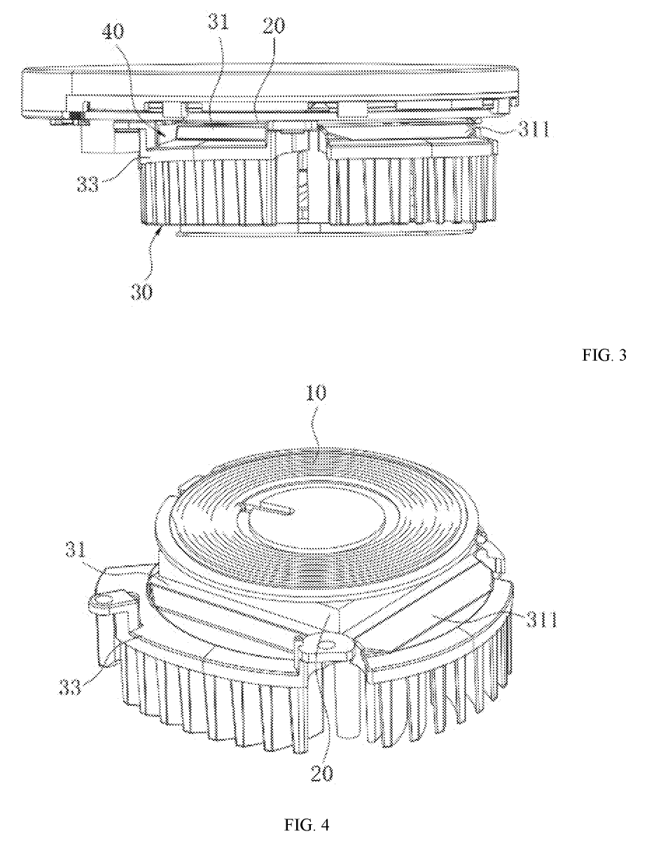

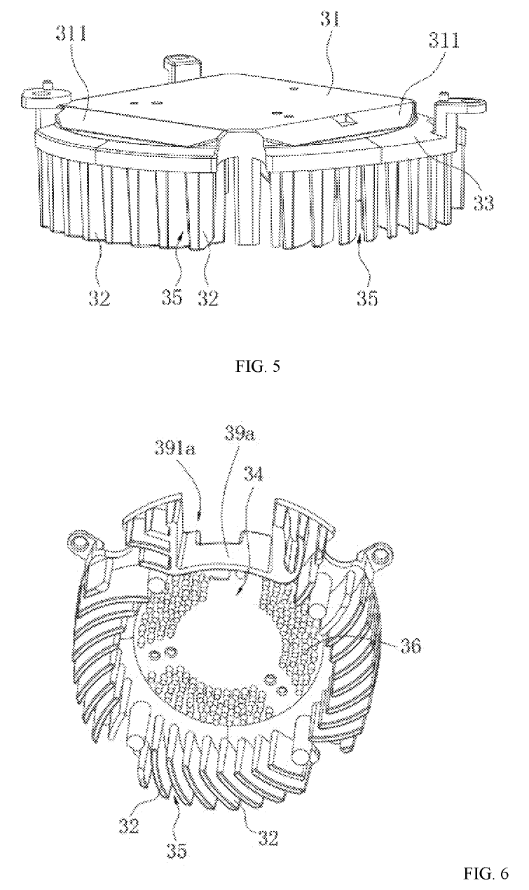

Continuing to refer to FIGS. 3 to 5, the cooler 20 has a cold end and a hot end disposed opposite each other, and the cold end of the cooler 20 is connected to the charging coil 10. The heat sink 30 may include a heat dissipation body 33, and the heat dissipation body 33 is connected to the hot end of the cooler 20. The heat dissipation body 33 is provided with an inclined surface 311, and the inclined surface 311, the cooler 20, and/ the heat dissipation body 33 define (e.g., enclose) a heat dissipation space 40.

The technical solution of the example is implemented to obtain the following beneficial effects: the wireless charging stand 100 of the technical solution is applied to a case of charging power-consuming devices such as mobile phones, and during use, a mobile phone is placed on the wireless charging stand 100 to energize the charging coil 10, and the charging coil 10 may charge the mobile phone wirelessly. During this process, the charging coil 10 continuously generates a large amount of heat, the heat may be conducted to the hot end of the cooler 20 via the cold end of the cooler 20, and then conducted into the heat sink 30 via the hot end, a part of the heat entering the heat sink 30 is directly dissipated to an external environment through a heat dissipation path of the heat sink 30, and another part of the heat reaches the heat dissipation space 40 enclosed by the inclined surface 311 and the heat dissipation body 33 to exchange heat with air in the heat dissipation space 40, thus being directly dissipated to the external environment, so that the heat in the heat sink 30 may be more efficiently dissipated via two heat dissipation paths. This method and structure improve the heat dissipation efficiency of the heat sink 30, strengthen the cooling effect on the charging coil 10, and ensure the charging efficiency of the mobile phone.

In addition, the heat sink 30 may be further provided with a boss 31, and the boss 31 is disposed on a side of the heat dissipation body 33 facing the hot end of the cooler 20. The boss 31 facilitates wire bonding.

Further, based on the above example, at least two inclined surfaces 311 are provided and sequentially arranged along a circumferential direction of the heat dissipation body 33, and all the inclined surfaces 311 and the cooler 20 enclose a heat dissipation space 40 of an annular shape.

For example, four inclined surfaces 311 are provided and all incline toward a direction away from the cooler 20 to form the heat dissipation space 40 of an annular structure, which greatly increases the contact area between the heat sink 30 and air compared with a heat dissipation space 40 disposed on a single side, thereby significantly increasing the heat exchange amount between the heat sink 30 and the air per unit time, and thus further strengthening the heat dissipation efficiency of the heat sink 30.

It should be noted that inclinations of the plurality of inclined surfaces 311 may be equal, or may be partially equal or completely unequal, which may be selected according to actual needs. The inclined surface 311 may be at least one of a flat surface, a convex curved surface, a concave curved surface, and the like.

Continuing to refer to FIGS. 6 and 8, further, in order to strengthen the heat dissipation efficiency of the heat sink 30, a side surface of the heat dissipation body 33 facing away from the cooler 20 is provided with a bump structure 36 configured to improve heat transfer efficiency between the heat sink 30 and the air. Specifically, the bump structure 36 includes a plurality of protrusions dispersedly arranged, and the protrusions can increase the contact area with the air, such that more heat is exchanged into the air per unit time, improving the heat dissipation efficiency.

For example, the structure and shape of the protrusion may be any one of a cylinder, a circular truncated cone, a tapered cylinder, and the like, which may be flexibly selected according to actual needs.

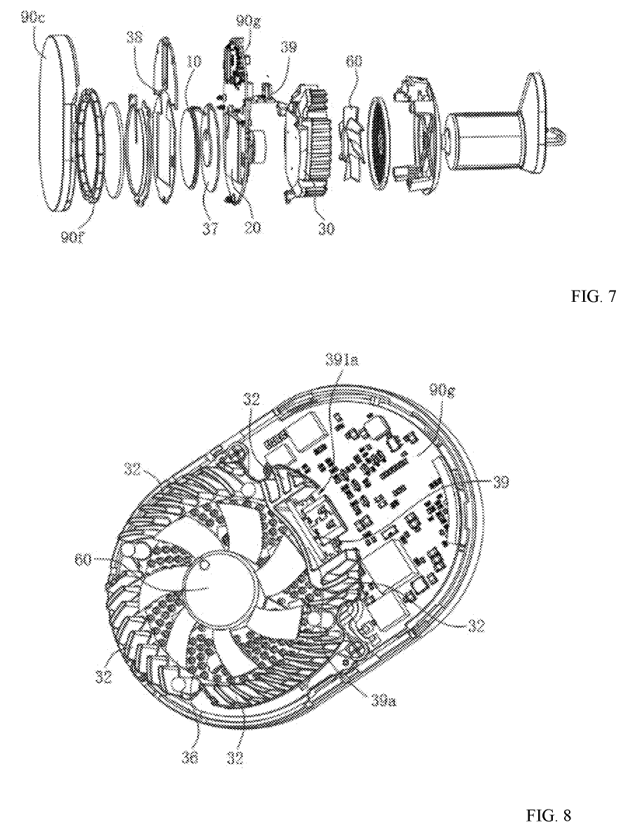

Continuing to refer to FIG. 7, the wireless charging stand 100 further includes a vapor chamber 37, and the vapor chamber 37 is disposed between the charging coil 10 and the cooler 20. The vapor chamber 37 enables the heat to be more uniform when conducted from the charging coil 10 to the cooler 20, thereby strengthening the heat dissipation efficiency and uniformity for the charging coil 10.

Continuing to refer to FIG. 7, in another example, the wireless charging stand 100 further includes a heat insulation layer 38 disposed behind the hot end of the cooler 20. The heat insulation layer 38 is configured to block the heat dissipated from the heat sink 30 from diffusing to the hot end of the cooler 20, thereby affecting heat dissipation efficiency of the charging coil 10.

For example, materials that can be used by the heat insulation layer 38 include, but are not limited to, glass fiber, asbestos, and the like.

Continuing to refer to FIGS. 1, 5, 6, and 8, the wireless charging stand 100 further includes a base housing 50, a sidewall of the base housing 50 is provided with a heat dissipation window 51, the heat sink 30 is disposed inside the base housing 50, and the heat sink 30 further includes heat dissipation fins 32, the heat dissipation fins 32 are mounted on a side surface of the heat dissipation body 33 facing away from the cooler 20, and the heat dissipation fins 32 face the heat dissipation window 51 or at least part of the heat dissipation fins 32 extend into the heat dissipation window 51.

During use, the heat generated by the charging coil 10 may be conducted to the heat sink 30 via the cooler 20, and then may be directly dissipated to the external environment directly through the heat dissipation window 51 with the aid of the heat dissipation fins 32, which significantly improves the heat dissipation efficiency compared to the related art in which the heat dissipation fins 32 first dissipate heat to an inner cavity of a housing and then dissipate heat through convection.

It should be noted that more than one heat dissipation window 51 may be provided. When two or more heat dissipation windows 51 are provided, the two or more heat dissipation windows 51 are arranged at intervals along a circumferential direction of the base housing 50. Each of the heat dissipation windows 51 is provided with the corresponding heat dissipation fin 32, such that the heat may be dissipated to the external environment through the plurality of heat dissipation windows 51 via the plurality of heat dissipation fins 32, improving the heat dissipation efficiency.

Continuing to refer to FIGS. 6 to 8, the wireless charging stand 100 further includes a wiring circuit board 39, the heat sink 30 further includes an extension portion 39a, the extension portion 39a is disposed on the side surface of the heat dissipation body 33 facing away from the cooler 20, the extension portion 39a encloses an installation recess 391a, the wiring circuit board 39 is disposed in the installation recess 391a, and at least part of the side surface of the extension portion 39a facing away from the installation recess 391a is provided with the heat dissipation fins 32.

On the one hand, forming the extension portion 39a by the heat sink 30 and mounting the wiring circuit board 39 into the installation recess 391a formed by the extension portion 39a may save installation space and make structural arrangement of various components more compact, which is conducive to a miniaturized design of the wireless charging stand 100; on the other hand, the wiring circuit board 39 also generates heat when conducting a current, and the heat is timely dissipated via the extension portion 39a and the heat dissipation fins 32, realizing timely and effective cooling and heat dissipation for the wiring circuit board 39, and eliminating a safety hazard potentially caused by overheating.

Continuing to refer to FIGS. 1, 2, 5, 6 and 8, the wireless charging stand 100 further includes a heat dissipation fan 60, a plurality of heat dissipation fins 32 are provided, the plurality of heat dissipation fins 32 are circumferentially disposed on the heat dissipation body 33 and are all inclined toward the same circumferential direction, and the plurality of heat dissipation fins 32, the cooler, and/or the heat dissipation body 33 may define (e.g., enclose) an accommodating cavity 34, the heat dissipation fan 60 is disposed in the accommodating cavity 34, and an inclination direction of fan blades of the heat dissipation fan 60 is the same as the inclination direction of the heat dissipation fins 32.

More specifically, both of the fan blades of the heat dissipation fan 60 and the heat dissipation fins 32 are in a curved shape, and bending directions thereof are the same.

Further, two adjacent heat dissipation fins 32 are disposed at intervals to form a heat dissipation channel 35, one end of the heat dissipation channel 35 is in communication with the accommodating cavity 34, and the other end of the heat dissipation channel 35 is in communication with the heat dissipation window 51, such that the heat dissipation fan 60 is in communication with the external environment.

During use, the heat dissipation fan 60 is energized, and the heat dissipation fan 60 blows air toward the heat dissipation fins 32, thereby accelerating the air in the heat dissipation channel 35 to flow toward the external environment through the heat dissipation window 51, such that more heat may be taken away per unit time, further improving the heat dissipation efficiency.

It should be noted that, when the heat is conducted to the heat sink 30 and blown outward as hot air by the internal heat dissipation fan 60, with the aid of the inclined surface 311 provided on the heat dissipation body 33, the inclined surface 311 is capable of guiding a portion of the hot air obliquely rearward, thereby preventing a user from contacting the hot air when picking up and placing the mobile phone and affecting user experience.

In addition, another portion of air volume is discharged from the heat dissipation channel 35 of the heat sink 30, thereby taking away the heat from the circuit board.

Continuing to refer to FIGS. 2, 7 and 8, for example, the circuit board includes, but is not limited to, a main circuit board 90g (configured to be electrically connected to the cooler 20, the charging coil 10, and the like to control operation thereof), the wiring circuit board 39, and the like.

Based on the above examples, the wireless charging stand 100 may further include a dust gauze 70, a bottom wall of the base housing 50 is provided with a vent, the dust gauze 70 is disposed between the bottom wall of the base housing 50 and the heat sink 30, and the dust gauze 70 covers the vent. When the heat dissipation fan 60 operates, the air in the external environment is drawn into a housing cavity through the vent, and then blown to the heat dissipation channel 35 by the heat dissipation fan 60, so as to discharge the heat. The dust gauze 70 is configured to block dust and other impurities in the air, avoiding the dust and other impurities from adhering to the fan blades and the heat dissipation fins 32 to cause contamination and simultaneously affect operation performance.

In order to avoid air leakage causing wind noise and simultaneously install and position the dust gauze 70 and the heat sink 30, an annular foam 80 is further disposed between the dust gauze 70 and the heat sink 30.

In addition, based on any one of the above examples, the wireless charging stand 100 may further include a surface cover 90c. The surface cover 90c is connected and fixed to the base housing 50, and a thermally conductive medium is disposed between the side surface of the surface cover 90c facing the base housing 50 and the charging coil 10.

The connection manner between the surface cover 90c and the base housing 50 may be at least one of a threaded connection, a snap-fit connection, an adhesive connection, a magnetic connection, a rivet connection, and the like. After the surface cover 90c and the base housing 50 are assembled to enclose a mounting cavity therebetween, and the mounting cavity is configured to accommodate functional components such as the charging coil 10, the cooler 20, and the like, which improves the whole structural compactness and is conducive to a miniaturized design of the wireless charging stand 100.

During use, cold amount generated by the cold end of the cooler 20 may be conducted to the surface cover 90c through the thermally conductive medium, and the surface cover 90c then conducts the cold amount to a surface of the mobile phone, achieving cooling of the mobile phone, and avoiding the mobile phone from heating up or even burning hands during charging to affect the user experience.

In an example, the thermally conductive medium may be, but is not limited to, silicone thermal grease, and the like.

The surface cover 90c uses a material having a relatively high thermal conductivity, such as glass, a ceramic plate, and the like.

Further, the wireless charging stand 100 may further include a cold conducting plate 90d disposed between the charging coil 10 and the cold end of the cooler 20. When the cooler 20 operates, the cold amount generated by the cold end may be more effectively conducted to the coil through the cold conducting plate 90d, thereby realizing cooling of the coil.

Continuing to refer to FIG. 2, in order to improve installation stability and reliability of the charging coil 10 and the cold conducting plate 90d, the wireless charging stand 100 further includes a carrier plate 90e disposed at the surface cover 90c, the carrier plate 90e is provided with a positioning recess 91e, and both the cold conducting plate 90d and the charging coil 10 are mounted in the positioning recess 91e.

For example, the positioning recess 91e is a circular recess, the cold conducting plate 90d and the charging coil 10 are both circular and are stacked and mounted in the positioning recess 91e, and the cold conducting plate 90d is located below the charging coil 10.

In actual use, there may be some obstacles in different usage scenarios and environments to cause installation interference to the wireless charging stand 100, or different users have specific use and operation preferences. Accordingly, in an example, the wireless charging stand 100 further includes a rotary body 90 and a fixed base 90a, a side surface of the fixed base 90a facing the rotary body 90 is recessed to form a rotary recess 91a, the rotary body 90 is disposed on the base housing 50, and the rotary body 90 is rotatably mounted in the rotary recess 91a.

In an example, the rotary body 90 is a spherical body, and the rotary recess 91a is a spherical recess. The rotary body 90 rotates 360° at any angle and direction within the rotary recess 91a, the wireless charging stand 100 forms different structural forms, thereby meeting different usage scenarios, spaces, and different preference requirements of different users, and improving an applicable scope and the user experience of the wireless charging stand 100.

Further, the wireless charging stand 100 may further include a fixing clamp 90b, and the fixing clamp 90b is disposed on the fixed base 90a. Compared to an installation manner in which the fixed base 90a is directly placed on a desktop, a vehicle central control desk, or the like, clamping installation with the fixing clamp 90b has higher stability and reliability, makes the wireless charging stand 100 less prone to looseness and inclination, and improves safety of the structure of the wireless charging stand 100 and the mobile phone. For example, the fixing clamp 90b may be a spring clamp or the like.

Continuing to refer to FIG. 7, in addition, the wireless charging stand 100 may further include a magnet 90f, and the magnet 90f is mounted on an inner side of the surface cover 90c and configured to magnetically position the mobile phone that needs to be charged on the surface of the surface cover 90c.

The technical features of the above-mentioned examples can be combined arbitrarily. For brevity of description, not all possible combinations of the technical features in the above examples are described. However, as long as there is no contradiction between these combinations of the technical features, the combinations should be considered as falling within the scope of the specification.

The examples described above represent only several examples of the present disclosure, which are described in detail but should not be construed as limitations of the scope of the disclosure. It should be noted that several variations and improvements can be made

without departing from the spirit of the disclosure for those skilled in the art, all of which fall within the scope of the present disclosure. Accordingly, the scope of the present disclosure should be subject to the appended claims.

What is claimed is:

1. A wireless charging stand, comprising:
a charging coil;
a cooler having a cold end and a hot end disposed opposite each other, the cold end being connected to the charging coil; and
a heat sink comprising a heat dissipation body connected to the hot end, wherein the heat dissipation body comprises an inclined surface, and the inclined surface and the cooler define a heat dissipation space.

2. The wireless charging stand of claim 1, wherein a side surface of the heat dissipation body facing away from the cooler comprises a bump structure.

3. The wireless charging stand of claim 1, further comprising a vapor chamber disposed between the charging coil and the cooler.

4. The wireless charging stand of claim 1, further comprising a heat insulation layer disposed behind the hot end of the cooler and configured to block heat dissipated from the heat sink from diffusing to the hot end of the cooler.

5. The wireless charging stand of claim 1, further comprising a base housing, wherein a sidewall of the base housing comprises a heat dissipation window, the heat sink is disposed inside the base housing, the heat sink comprises heat dissipation fins mounted on a side surface of the heat dissipation body facing away from the cooler, and the heat dissipation fins facing the heat dissipation window or at least part of the heat dissipation fins that extend into the heat dissipation window.

6. The wireless charging stand of claim 5, further comprising a wiring circuit board, wherein the heat sink comprises an extension portion disposed on the side surface of the heat dissipation body facing away from the cooler and enclosing an installation recess, the wiring circuit board is disposed in the installation recess, and at least part of a side surface of the extension portion facing away from the installation recess is provided with the heat dissipation fins.

7. The wireless charging stand of claim 5, further comprising a heat dissipation fan, wherein a plurality of the heat dissipation fins are circumferentially disposed on the heat dissipation body and are inclined toward a same circumferential direction, the plurality of heat dissipation fins and the heat dissipation body define an accommodating cavity, and two adjacent heat dissipation fins are disposed at intervals to form a heat dissipation channel, one end of the heat dissipation channel is in communication with the accommodating cavity, and the other end of the heat dissipation channel is in communication with the heat dissipation window.

8. The wireless charging stand of claim 5, further comprising:
a dust gauze, wherein a bottom wall of the base housing comprises a vent, the dust gauze is disposed between the bottom wall of the base housing and the heat sink, and the dust gauze covers the vent;
a rotary body and a fixed base, wherein a side surface of the fixed base facing the rotary body is recessed to form a rotary recess, the rotary body is disposed on the base housing, and the rotary body is rotatably mounted in the rotary recess; and
a fixing clamp disposed on the fixed base.

9. The wireless charging stand of claim 5, further comprising a surface cover connected and fixed to the base housing, wherein a thermally conductive medium is disposed between the side surface of the surface cover facing the base housing and the charging coil.

10. The wireless charging stand of claim 9, further comprising a cold conducting plate disposed between the charging coil and the cold end of the cooler.

11. The wireless charging stand of claim 10, further comprising a carrier plate disposed at the surface cover, wherein the carrier plate comprises a positioning recess, and both the cold conducting plate and the charging coil are mounted in the positioning recess.

12. A wireless charging stand comprising:
a charging coil;
a cooler having a cold end and a hot end disposed opposite each other, the cold end being connected to the charging coil; and
a heat sink comprising a heat dissipation body connected to the hot end, the heat dissipation body provided with at least two inclined surfaces sequentially arranged along a circumferential direction of the heat dissipation body, the at least two inclined surfaces and the cooler defining a heat dissipation space.

13. The wireless charging stand of claim 12, further comprising a vapor chamber disposed between the charging coil and the cooler.

14. The wireless charging stand of claim 12, further comprising a heat insulation layer disposed behind the hot end of the cooler and configured to block heat dissipated from the heat sink from diffusing to the hot end of the cooler.

15. The wireless charging stand of claim 12, further comprising a heat dissipation fan disposed in an accommodating cavity enclosed by heat dissipation fins and the heat dissipation body, the heat dissipation fan configured to accelerate airflow through heat dissipation channels formed between adjacent heat dissipation fins.

16. A wireless charging system comprising:
a wireless charging stand comprising:
a charging coil configured to wirelessly charge a mobile device;
a cooler having a cold end thermally coupled to the charging coil and a hot end opposite the cold end; and
a heat sink comprising a heat dissipation body thermally coupled to the hot end, the heat dissipation body having an inclined surface that defines a heat dissipation space with the cooler, the heat dissipation space configured to exchange heat with ambient air; and
a base housing enclosing the charging coil, the cooler, and the heat sink, the base housing having a sidewall provided with a heat dissipation window.

17. The wireless charging system of claim 16, wherein the heat sink further comprises heat dissipation fins mounted on a side surface of the heat dissipation body facing away from the cooler, the heat dissipation fins facing the heat dissipation window or at least part of the heat dissipation fins extending into the heat dissipation window.

18. The wireless charging system of claim 17, further comprising a heat dissipation fan disposed in an accommodating cavity enclosed by the heat dissipation fins and the heat dissipation body, wherein adjacent heat dissipation fins are disposed at intervals to form a heat dissipation channel in communication with the accommodating cavity and the heat dissipation window.

19. The wireless charging system of claim 16, further comprising a vapor chamber disposed between the charging coil and the cooler.

20. The wireless charging system of claim 16, further comprising a surface cover connected and fixed to the base housing, wherein a thermally conductive medium is disposed between a side surface of the surface cover facing the base housing and the charging coil, and a magnet mounted on an inner side of the surface cover and configured to magnetically position a mobile device on the surface cover.
